(19) United States
(12) Patent Application Publication
(10) Pub. No.: US 2011/0057307 A1
(43) Pub. Date: Mar. 10, 2011

(54) Semiconductor Chip with Stair Arrangement Bump Structures

(76) Inventors: Roden R. Topacio, Markham (CA); Yip Seng Low, Thornhill (CA)

(21) Appl. No.: 12/557,336

(22) Filed: Sep. 10, 2009

(51) Int. Cl. H01L 23/498; H01L 21/60

(52) U.S. Cl. 257/737; 438/613; 438/106; 257/E21.509; 257/E21.508; 257/E23.068

(57) ABSTRACT

Various semiconductor chip input/output structures and methods of making the same are disclosed. In one aspect, a method of manufacturing is provided that includes forming a first conductor structure on a first side of a semiconductor chip and forming a second conductor structure in electrical contact with the first conductor structure. The second conductor structure is adapted to be coupled to a solder structure and includes a stair arrangement that has at least two treads.

### BACKGROUND OF THE INVENTION

1. Field of the Invention

This invention relates generally to semiconductor processing, and more particularly to semiconductor chip solder bump pads and methods of making the same.

2. Description of the Related Art

Flip-chip mounting schemes have been used for decades to mount semiconductor chips to circuit boards, such as semiconductor chip package substrates. In many conventional flip-chip variants, a plurality of solder joints are established between input/output (I/O) sites of a semiconductor chip and corresponding I/O sites of a circuit board. In one conventional process, a solder bump is metallurgically bonded to a given I/O site or pad of the semiconductor chip and a so-called pre-solder is metallurgically bonded to a corresponding I/O site of the circuit board. Thereafter the solder bump and the pre-solder are brought into proximity and subjected to a heating process that reflows one or both of the solder bump and the pre-solder to establish the requisite solder joint.

In one conventional process, the connection of the solder bump to a particular I/O site of a semiconductor chip entails forming an opening in a top-level dielectric film of a semiconductor chip proximate the I/O site and thereafter depositing metal to establish an under bump metallization (UBM) structure. The solder bump is then metallurgically bonded to the UBM structure by reflow. This conventional UBM structure includes a base, a sidewall and an upper flange that is positioned on the dielectric film.

Flip-chip solder joints may be subjected to mechanical stresses from a variety of sources, such as coefficient of thermal expansion mismatches, ductility differences and circuit board warping. Such stresses can subject the just described conventional UBM structure to bending moments. The effect is somewhat directional in that the stresses tend to be greatest nearer the die edges and corners and fall off with increasing proximity to the die center. The bending moments associated with this so-called edge effect can impose stresses on the dielectric film beneath the UBM structure that, if large enough, can produce fracture.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a first conductor structure on a first side of a semiconductor chip and forming a second conductor structure in electrical contact with the first conductor structure. The second conductor structure is adapted to be coupled to a solder structure and includes a stair arrangement that has at least two treads.

In accordance with another aspect of an embodiment of the present invention, a method of coupling a semiconductor chip to a circuit board is provided that includes coupling a first solder structure to a first conductor structure that is positioned on a first side of the semiconductor chip. The first conductor structure includes a stair arrangement that has at least two treads. The first solder structure is coupled to the circuit board.

In accordance with another aspect of an embodiment of the present invention, an apparatus is provided that includes a semiconductor chip that has a first side and second side opposite to the first side. A first conductor structure is positioned on the first side and adapted to be coupled to a solder structure. The first conductor structure includes a stair arrangement that has at least two treads.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a semiconductor chip device that includes a semiconductor chip mounted on a circuit board;

FIG. 2 is a sectional view of FIG. 1 taken at section 2-2;

FIG. 3 is a sectional view of a portion of a conventional solder joint;

FIG. 4 is a portion of FIG. 2 shown at greater magnification;

FIG. 5 is a sectional view depicting an exemplary formation of an opening to a conductor structure of a semiconductor chip;

FIG. 6 is a sectional view like FIG. 5, but depicting application of an insulating layer and mask;

FIG. 7 is a sectional view like FIG. 6, but depicting formation of an opening in the insulating layer;

FIG. 8 is a sectional view like FIG. 7 depicting formation of another conductor structure in the opening with a stair arrangement;

FIG. 9 is a plan view of the stair arrangement conductor structure of FIG. 8; and

FIG. 10 is a sectional view like FIG. 8 but schematically depicting formation of a solder structure on the stair conductor structure.

### DETAILED DESCRIPTION OF SPECIFIC EMBODIMENTS

Various embodiments of a semiconductor chip are described herein. One example includes solder bump connection structures, such as UBM structures, fabricated with a stair arrangement with two or more treads. The stair arrangement spreads stresses from a solder joint over a larger area to reduce the possibility of underlying passivation stack damage. Additional details will now be described.

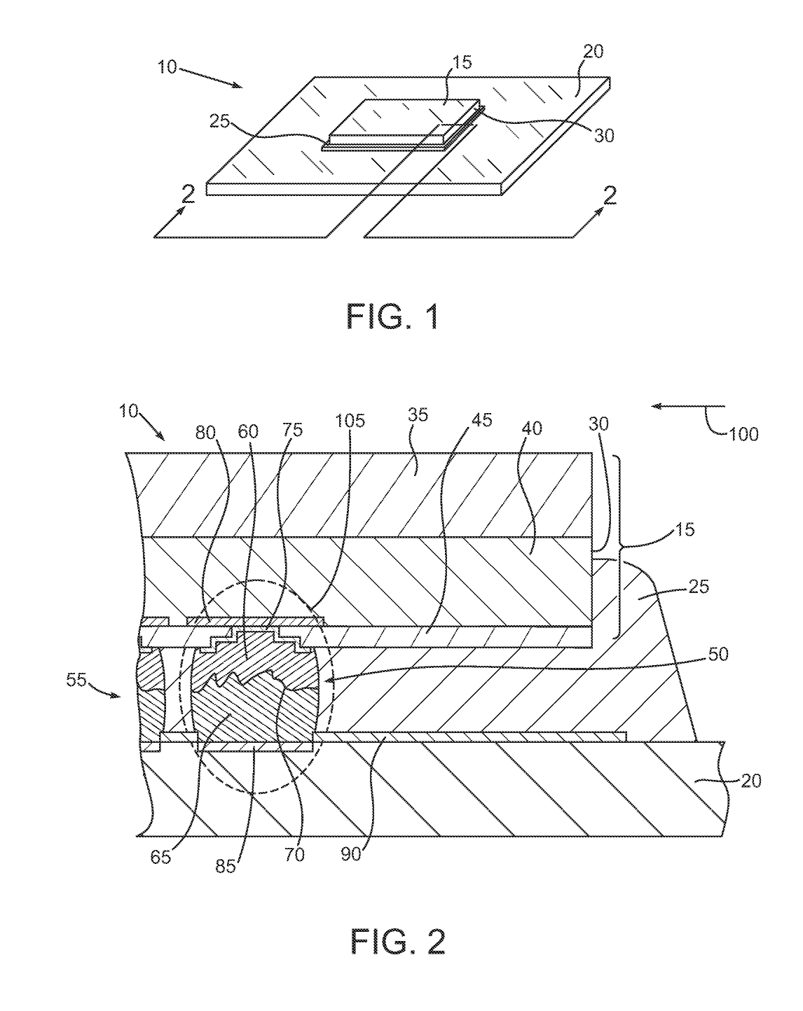

In the drawings described below, reference numerals are generally repeated where identical elements appear in more than one figure. Turning now to the drawings, and in particular to FIG. 1, therein is shown a pictorial view of an exemplary embodiment of a semiconductor chip device 10 that includes a semiconductor chip 15 mounted on a circuit board 20. An underfill material layer 25 is positioned between the semiconductor chip 15 and the circuit board 20. The semiconductor chip 15 may be any of a myriad of different types of circuit devices used in electronics, such as, for example, microprocessors, graphics processors, combined microprocessor/graphics processors, application specific integrated circuits, memory devices or the like, and may be single or multi-core or even stacked with additional dice. The semiconductor chip 15 may be constructed of bulk semiconductor, such as silicon or germanium, or semiconductor on insulator materials, such as silicon-on-insulator materials. The semiconductor chip 15 may be flip-chip mounted to the circuit board 20 and electrically connected thereto by solder joints or other structures (not visible in FIG. 1 but shown in subsequent figures).

The circuit board 20 may be a semiconductor chip package substrate, a circuit card, or virtually any other type of printed circuit board. Although a monolithic structure could be used for the circuit board 20, a more typical configuration will utilize a build-up design. In this regard, the circuit board 20 may consist of a central core upon which one or more build-up layers are formed and below which an additional one or more build-up layers are formed. The core itself may consist of a stack of one or more layers. One example of such an arrangement may be termed a so called “2-2-2” arrangement where a single-layer core is laminated between two sets of two build-up layers. If implemented as a semiconductor chip package substrate, the number of layers in the circuit board 20 can vary from four to sixteen or more, although less than four may be used. So-called “coreless” designs may be used as well. The layers of the circuit board 20 may consist of an insulating material, such as various well-known epoxies, interspersed with metal interconnects. A multi-layer configuration other than buildup could be used. Optionally, the circuit board 20 may be composed of well-known ceramics or other materials suitable for package substrates or other printed circuit boards.

The circuit board 20 is provided with a number of conductor traces and vias and other structures in order to provide power, ground and signals transfers between the semiconductor chip 15 and another circuit device that is not shown. To facilitate those transfers, the circuit board 20 may be provided with input/outputs in the form of a pin grid array, a ball grid array, a land grid array or other type of interconnect scheme.

Additional details of the semiconductor chip 15 will be described in conjunction with FIG. 2, which is a sectional view of FIG. 1 taken at section 2-2. Before turning to FIG. 2, it will be helpful to note the exact location of the portion of the package 10 that will be shown in section. Note that section 2-2 passes through a small portion of the semiconductor chip 15 that includes an edge 30. With that back drop, attention is now turned to FIG. 2. As noted above, the semiconductor chip 15 may be configured as a bulk semiconductor or a semiconductor-on-insulator configuration. In this illustrative embodiment, the semiconductor chip 15 is implemented as bulk semiconductor that includes a bulk semiconductor layer 35, and a semiconductor device layer 40. The semiconductor device layer 40 includes the various circuits that provide the functionality for the semiconductor chip 15 and will typically include plural metallization and/or other types of conductor layers that facilitate the transfer of power ground and signals to and from the semiconductor chip 15. A dielectric laminate layer 45 is formed on the semiconductor device layer 40 and may consist of multiple layers of insulating material. More details regarding the dielectric laminate 45 will be described in conjunction with a subsequent figure. The semiconductor chip 15 may be flip-chip mounted to the carrier substrate 20 and electrically connected thereto by way of a plurality of solder structures or joints, two of which are visible and labeled 50 and 55 respectively. Only a portion of the solder joint 55 is visible due to the positioning of section 2-2.

The following description of the solder joint 50 will be illustrative of the other solder joints as well. The solder joint 50 includes a solder structure or bump 60 that is metallurgically bonded to another solder structure 65 that is sometimes referred to as a pre-solder. The solder bump 60 and the pre-solder 65 are metallurgically joined by way of a solder re-flow process. The irregular line 70 denotes the hypothetical border between the solder bump 60 and pre-solder 65 following the re-flow. However, the skilled artisan will appreciate that such a border 70 is seldom that readily visible even during microscopic examination. The solder bump 60 may be composed of various lead-based or lead-free solders. An exemplary lead-based solder may have a composition at or near eutectic proportions, such as about 63% Sn and 37% Pb. Lead-free examples include tin-silver (about 97.3% Sn 2.7% Ag), tin-copper (about 99% Sn 1% Cu), tin- silver-copper (about 96.5% Sn 3% Ag 0.5% Cu) or the like. The pre-solder 65 may be composed of the same types of materials. Optionally, the pre-solder 65 may be eliminated in favor of a single solder structure or a solder plus a conducting post arrangement. The solder bump 60 is metallurgically connected to a conductor structure 75 that is alternatively termed an underbump metallization or UBM structure. As described in more detail elsewhere herein, the UBM structure 75 may be provided with a stair arrangement that provides improved resistance to various stresses and bending moments. The UBM structure 75 is, in turn, electrically connected to another conductor structure or pad in the chip 15 that is labeled 80 and may be part of the plural metallization layers in the semiconductor chip 15. The conductor structure 80 may be termed a redistribution layer or RDL structure. The conductor structure 80 may be used as an input/output site for power, ground or signals or may be used as a dummy pad that is not electrically tied to other structures. The pre-solder 65 is similarly metallurgically bonded to a conductor 85 that is bordered laterally by a solder mask 90. The conductor structure 85 may form part of what may be multiple layers of conductor structures and interconnected by vias and surrounded by dielectric material layers.

The underfill material layer 25 is dispersed between the semiconductor chip 15 and the substrate 20 to reduce the effects of differences in the coefficients of thermal expansion (CTE) of the semiconductor chip 15, the solder joints 50, 55 etc. and the circuit board 20. The underfill material layer 25 may be, for example, an epoxy resin mixed with silica fillers and phenol resins, and deposited before or after the re-flow process to establish the solder joints 50 and 55.

A variety of physical processes may lead to significant stresses on the intrmetallic bond between the solder bump 60 and the UBM structure 75. Some of these stresses are due to differences in strain rate between the semiconductor chip 15, the circuit board 20 and the underfill material layer 25 during thermal cycling. Another contributor to the differential stresses may be ductility differences between the solder bump 60 and the pre-solder 65. Due to a phenomena known as edge effect, these differential stresses and resultant strains may be greatest proximate the edge 30 of the semiconductor chip 15 and may progressively lessen in the direction indicated by the arrow 100 projecting away from the edge 30 and towards the center of the semiconductor chip 15.

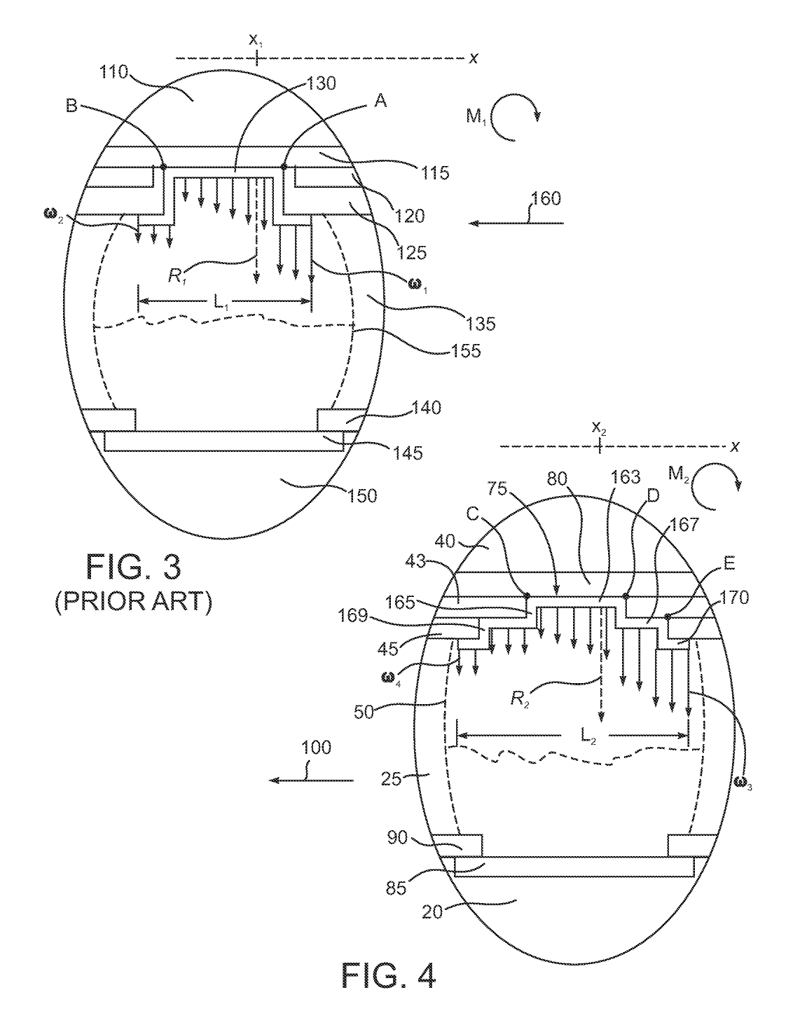

To aid in the description of the UBM structure 75, the portion of FIG. 2 circumscribed by the dashed oval 105 will be shown in greater magnification in FIG. 4. However, before turning to FIG. 4 in earnest, it will be useful to contrast a similar conventional structure for a solder joint and conductor pad arrangement. In this regard, attention is turned now to FIG. 3 which depicts a conventional solder joint and conductor pad arrangement in section. In order to clearly depict the various forces that are exerted against the pertinent structures, cross hatching is not shown in FIG. 3. Here, the following features are visible: a small portion of a semiconductor chip 110, a bump pad 115, a dielectric stack 120, a polymeric material layer 125, a UBM structure 130, an underfill material layer 135, a solder mask 140, a conductor pad 145 and a small portion of a semiconductor chip package substrate 150. The solder joint 155 is shown as a dashed figure. The direction to the center of the semiconductor chip 110 is indicated by the arrow 160.

Due to warping of the substrate 150 during manufacture, reliability testing or device operation and principally due to CTE mismatch, the substrate 150 through the solder joint 155 imparts a distributed load represented schematically by the series of downwardly pointing arrows. The distributed load varies in intensity from a maximum ω₁ to a minimum ω₂ along a length L₁ where ω₁ and ω₂ are in units of force per unit length. The resultant R₁ of the distributed load is located at point x₁ on the x-axis. The distributed load acting on the UBM structure 130 appears as a line distribution since FIG. 3 is a sectional view. In practice, the distributed load will be an area distribution. The gradual decrease in the force intensity ω₁ to ω₂ as a function of the distance along the x-axis in the direction 160 toward the center is due to the edge effect described in the Background section hereof. The position of the resultant R₁ relative to the corner point B produces a moment M₁ acting on the UBM structure 130 about corner point B. The corner point B can act as a pivot point for unwanted pivoting movement of the UBM structure 130 downward and about point B depending upon the ductility of the UBM structure 130 and the distance L₁. In essence, the distance L₁ may be small enough that the UBM structure 130 lacks sufficient ductility to be able to flex and accommodate the bending moment M₁ without delamination or the cracking of the dielectric stack 120, particularly near the corner point A.

Attention is turned again to the exemplary embodiment depicted in FIGS. 2 and 4. FIG. 4 depicts a portion of FIG. 2 circumscribed by the dashed oval 105 at greater magnification. This illustrative embodiment includes a configuration for the UBM structure 75 that addresses the issue of bending moments associated with edge effect and CTE mismatch just described in conjunction with the conventional solder joint UBM structure design in conjunction with FIG. 3. Like the depiction in FIG. 3, FIG. 4 does not include the traditional cross hatching that would normally be present in a patent drawing so that the various forces may be more clearly seen. It should be recalled that FIG. 4 depicts a small portion of the semiconductor chip device layer 40, the conductor pad 80, the dielectric laminate 43, the polymeric material layer 45, the UBM structure 75, the underfill material 25, the solder joint 50 (shown in dashed), the conductor pad 85, the solder mask 90 and a small portion of the circuit board 20. It should be noted that the dielectric stack may be monolithic or a laminate of multiple layers. In an exemplary embodiment, the dielectric stack may consist of alternating layers of, for example, silicon dioxide and silicon nitride.

As with the conventional embodiment depicted in FIG. 3, this illustrative embodiment may produce a distributed load on the UBM structure 75 that varies from some maximum intensity ω₃ to a minimum ω₄ along a length L₂ where ω₃ and ω₄ are in units of force per unit length. The resultant R₂ is located at point x₂ along the x-axis. The distributed load is due to warpage and other CTE effects of the substrate 20, and the variation in intensity is due to the aforementioned edge effect proceeding toward the center of the semiconductor chip along the x-axis in the direction of arrow 100. The distributed load acting on the UBM structure 75 appears as a line distribution since FIG. 4 is a sectional view. In practice, the distributed load will be an area distribution. The position of the resultant R₂ relative to the corner point C produces a moment M₂ acting on the UBM structure 75 about corner point C. However, the UBM structure 75 is manufactured with a stair arrangement so that the moment M₂ is resisted not only at a corner D, but also at another corner point E. In essence, the load is distributed over a longer length and thus area, which results in lower stress and less potential for delamination and cracking of the insulating stack 43. The stair arrangement includes a landing 163, a rise 165 projecting from the landing 163, a tread 167 extending from the rise 163, another rise 169 projecting from the tread 167 and another tread 170 extending from the rise 169. However, the number of treads could be greater than two. In this illustrative embodiment, the tread 167 is wider than the tread 170, but the two treads 167 and 170 could be equal in length or the tread 170 could be wider than the tread 167.

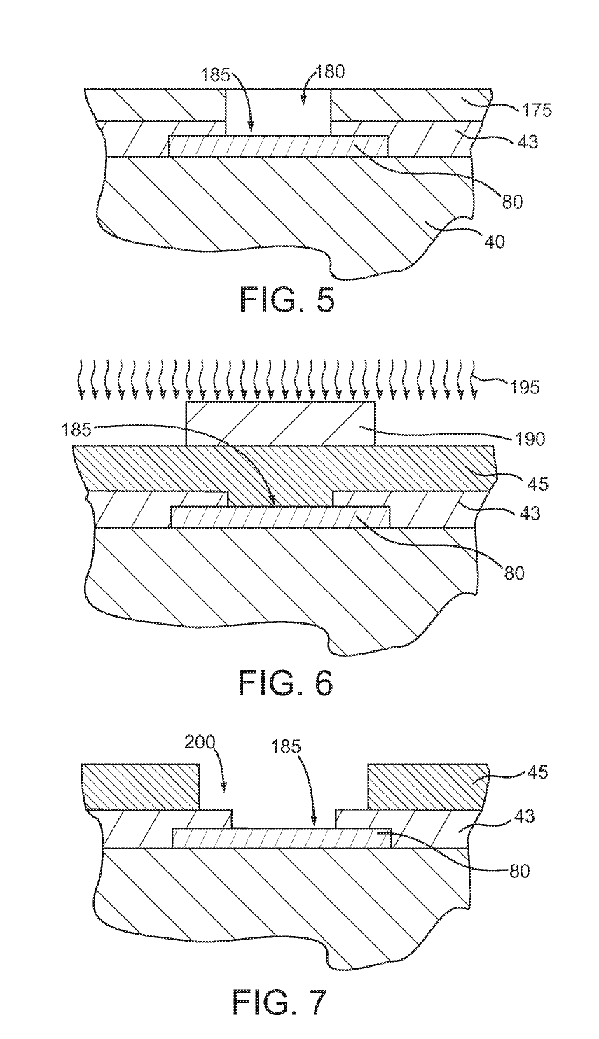

An exemplary method for fabricating the exemplary UBM structure 75 may be understood by referring now to FIGS. 5, 6, 7, 8, 9 and 10 and initially to FIG. 5. FIG. 5 is a sectional view that shows a small portion of the semiconductor chip device layer 40 and the conductor pad 80 and the dielectric stack 43. It should be understood that FIG. 5 depicts the semiconductor device layer 40 and the conductor pad 80 flipped over from the orientation depicted in FIGS. 2 and 4. It should also be understood that the process described herein could by performed at the wafer level or on a die by die basis. At this stage, conductor structure 80 and the dielectric stack 43 have been formed. The conductor structure 80 may be composed of a variety of conductor materials, such as aluminum, copper, silver, gold, titanium, refractory metals, refractory metal compounds, alloys of these or the like. In lieu of a unitary structure, the conductor structure 80 may consist of a laminate of plural metal layers, such as a titanium layer followed by a nickel-vanadium layer followed by a copper layer. In another embodiment, a titanium layer may be covered with a copper layer followed by a top coating of nickel. However, the skilled artisan will appreciate that a great variety of conducting materials may be used for the conductor structure 80. Various well-known techniques for applying metallic materials may be used, such as physical vapor deposition, chemical vapor deposition, plating or the like. It should be understood that additional conductor structures could be used.

The dielectric stack 43 may consist of alternating layers of dielectric materials, such as silicon dioxide and silicon nitride, and may be formed by well-known chemical vapor deposition (CVD) and/or oxidation or oxidation techniques. A suitable lithography mask 175 may be formed on the dielectric stack 43 and by well-known lithography steps patterned with a suitable opening 180 in alignment with the conductor pad 80. Thereafter, one or more material removal steps may be performed in order to produce the opening 185 in the dielectric stack 43. For example, the material removal steps may include one or more dry and/or wet etching processes suitable for the particular materials selected for the dielectric stack 43. Following the material removal to yield the opening 185, the mask 175 may be stripped by ashing, solvent stripping or the like.

Referring now to FIG. 6, the polymer layer 45 is formed on the dielectric stack 43. The polymer layer 45 may be composed of polyimide, benzocyclobutene or the like, or other insulating materials such as silicon nitride or the like and may be deposited by spin coating, CVD or other techniques. The application of the layer 45 will typically fill the opening 185 in the dielectric stack 43. In order to produce the stair-stepped arrangement for the subsequently formed UBM structure, it is necessary to establish an opening in the polymer layer 45 that is wider than the opening 185 in the dielectric stack 43. This may be accomplished in a variety of ways depending on the composition of the polymer layer 45. In an exemplary embodiment utilizing polyimide as the polymer layer 45, the polyimide may be infused with a photoactive compound(s) and a suitable non-contact mask 195 placed over the desired location of the opening in the polymer layer 45. Next the polymer layer 45 is exposed with radiation 195. The portions of the polymer layer 45 not covered by the mask 190 are rendered insoluble in a developer solution. The non-contact mask 190 is removed and the polymer layer 45 developed to yield the opening 200 as shown in FIG. 7. If the polymer layer 45 is not capable of material removal by way of exposure and developing, then a suitable lithography mask may be applied and an etch performed to yield the opening 200.

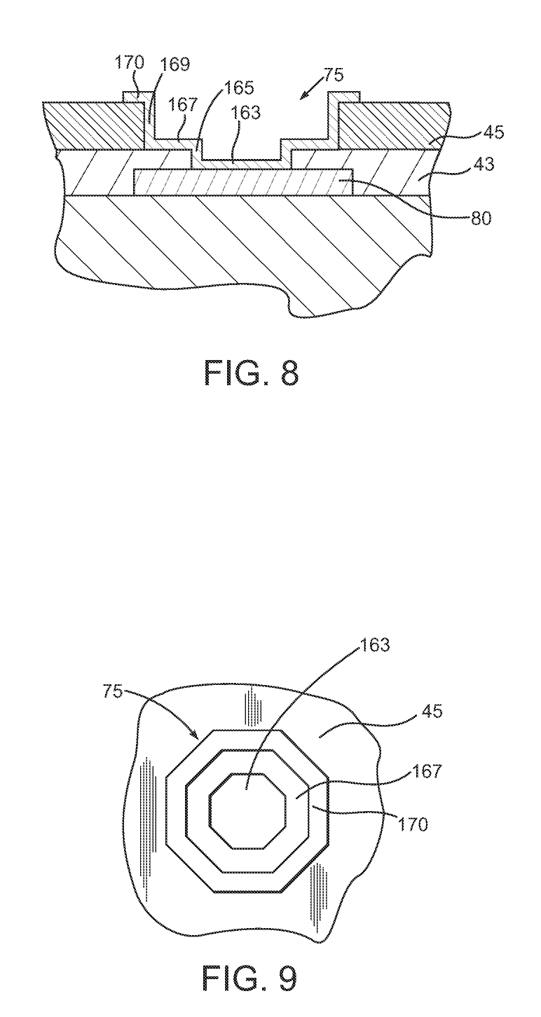

Referring now to FIG. 8, the UBM structure 75 may be formed by deposition, plating or other material formation techniques. Indeed, the same types of materials and techniques described in conjunction with the conductor structure 80 could be used for the UBM structure 75 as well. In this exemplary embodiment, the UBM structure 75 may be formed by plating copper across the surface of the polymer layer 45 followed by a material removal step to leave just the UBM structure 75. The material removal may be by wet or dry etching. At this stage, the UBM structure 75 includes the aforementioned base 163, rises 165 and 169, and treads 167 and 170. The UBM structure 75 forms a metallurgical bond with the underlying conductor pad 80. If necessary, a preliminary native oxide strip etch may be performed to ensure that the surface of the conductor pad 80 is sufficiently exposed to enable metallurgical bonding with the UBM structure 75.

FIG. 9 is an overhead view of the UBM structure 75 following the plating and etch definition thereof. In this illustrative embodiment, the UBM structure 75 may have the generally octagonal shape as shown in FIG. 9. Note the landing 163 and the treads 167 and 170 are clearly visible and have the same general octagonal footprint. It should be understood, however, that virtually any other shape besides an octagonal footprint may be provided for the UBM structure 75.

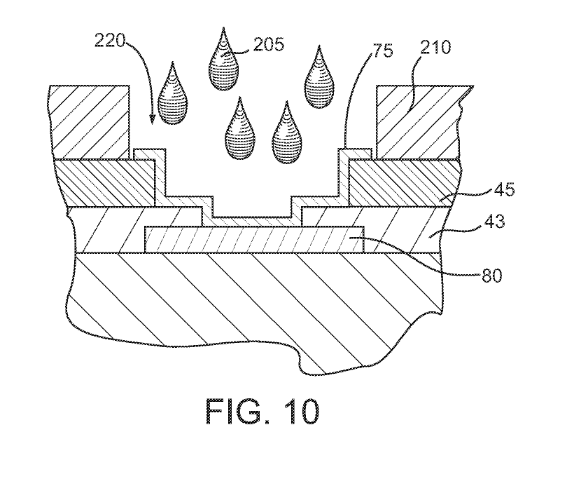

Attention is now turned to FIG. 10, which depicts schematically the deposition of solder 205 which is destined to become the solder bump 60 depicted in FIG. 2. A variety of processes may be used in conjunction with the deposited solder 205 in order to establish the solder bump 60 depicted in FIG. 2. In one illustrative embodiment, a printing process is used which may include the sputter deposition of titanium on the UBM structure 75 followed by blanket sputtering of a nickel-vanadium film and then followed by a blanket sputtering of a copper film. At this point, a suitable lithography mask 210 may be applied to the polymer layer 45. The lithography mask 210 may be fashioned with an opening 220 by well-known lithography processes. The solder 205 is then deposited by a screen printing process. In an alternate exemplary embodiment, a plating process may be used. In this regard, the titanium and copper may be sequentially blanket sputtered on the UBM structure 75 and the polymer layer 45. Next, a suitable lithography mask, not unlike the mask 210 depicted in FIG. 9, may be formed with an opening to expose the UBM structure 75. At this stage, nickel may be plated to the UBM structure and the solder 205 may be plated to the nickel. Following the plating of the solder 205, the mask may be chemically stripped to leave the aforementioned solder bump 60 depicted in FIG. 2.

Any of the exemplary embodiments disclosed herein may be embodied in instructions disposed in a computer readable medium, such as, for example, semiconductor, magnetic disk, optical disk or other storage medium or as a computer data signal. The instructions or software may be capable of synthesizing and/or simulating the circuit structures disclosed herein. In an exemplary embodiment, an electronic design automation program, such as Cadence APD, Encore or the like, may be used to synthesize the disclosed circuit structures. The resulting code may be used to fabricate the disclosed circuit structures.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a first conductor structure on a first side of a semiconductor chip; and
forming a second conductor structure in electrical contact with the first conductor structure and adapted to be coupled to a solder structure, the second conductor structure including a stair arrangement having at least two treads.

2. The method of claim 1, wherein the semiconductor chip includes a dielectric laminate positioned over the first conductor structure, the method comprising forming an opening to the first conductor structure and forming the second conductor structure in the opening.

3. The method of claim 1, comprising coupling a solder structure to the second conductor structure.

4. The method of claim 1, wherein the solder structure comprises one of a solder bump and a solder joint.

5. The method of claim 1, comprising electrically coupling a circuit board to the solder structure.

6. The method of claim 5, wherein the circuit board comprises a semiconductor chip package substrate.

7. The method of claim 1, comprising forming the first and second conductor structures using instructions stored in a computer readable medium.

8. The method claim 1, wherein the first conductor structure comprises a dummy pad.

9. A method of coupling a semiconductor chip to a circuit board, comprising:
coupling a first solder structure to a first conductor structure positioned on a first side of the semiconductor chip, the first conductor structure including a stair arrangement having at least two treads; and
coupling the first solder structure to the circuit board.

10. The method of claim 9, wherein the first solder structure comprises one of a solder bump and solder joint.

11. The method of claim 9, wherein the coupling the first solder structure to the circuit board comprises coupling the first solder structure to a presolder coupled to the circuit board.

12. The method of claim 9, wherein the circuit board comprises a semiconductor chip package substrate.

13. An apparatus, comprising:
a semiconductor chip including a first side and second side opposite to the first side; and
a first conductor structure on the first side and adapted to be coupled to a solder structure, the first conductor structure having a stair arrangement including at least two treads.

14. The apparatus of claim 13, comprising a solder structure coupled to the first conductor structure.

15. The apparatus of claim 14, wherein the solder structure comprises one of a solder bump and solder joint.

16. The apparatus of claim 14, comprising a circuit board electrically coupled to the solder structure.

17. The apparatus of claim 16, wherein the circuit board comprises a semiconductor chip package substrate.

18. The apparatus of claim 13, comprising a second conductor structure of the semiconductor chip coupled to the first conductor structure.

19. The apparatus of claim 13, wherein the first conductor structure comprises an input/output pad.

20. The apparatus of claim 13, wherein the first conductor structure comprises a dummy pad.
